(19) United States
(12) Patent Application Publication
(10) Pub. No.: US 2012/0043634 A1
(43) Pub. Date: Feb. 23, 2012

(54) METHOD OF MANUFACTURING MICROLENS ARRAY, METHOD OF MANUFACTURING SOLID-STATE IMAGE SENSOR, AND SOLID-STATE IMAGE SENSOR

(75) Inventor: Masaki Kurihara, Koza-gun (JP)

(73) Assignee: CANON KABUSHIKI KAISHA, Tokyo (JP)

(21) Appl. No.: 13/198,258

(22) Filed: Aug. 4, 2011

(30) Foreign Application Priority Data
Aug. 17, 2010 (JP) 2010-182592
Jul. 25, 2011 (JP) 2011-162454

(51) Int. Cl. H01L 31/0232; G03F 7/40; H01L 31/18

(52) U.S. Cl. 257/432; 438/69; 430/321; 257/E31.127

(57) ABSTRACT

A method of manufacturing a microlens array includes forming a resist film on a structure including a plurality of light-receiving portions, exposing the resist film using a photomask in which a plurality of lens patterns for forming a plurality of microlenses are arranged, forming a resist pattern by developing the exposed resist film, and forming the plurality of microlens by annealing the resist pattern, wherein the plurality of lens patterns include lens patterns having exposure light transmittance distributions different from each other.

### BACKGROUND OF THE INVENTION

1. Field of the Invention

The present invention relates to a method of manufacturing a microlens array, a method of manufacturing a solid-state image sensor, and the solid-state image sensor.

2. Description of the Related Art

In a solid-state image sensor, to increase light collection efficiency to a light-receiving portion, a microlens is arranged for each pixel so as to correspond to each light-receiving portion. A color solid-state image sensor can have, for example, red, green, and blue color filters. Since a material forming a microlens has a wavelength dispersion of refractive index, microlenses having the same shape have different focal positions depending on the wavelengths of incident light. Japanese Patent Laid-Open No. 7-38075 discloses a method of forming red, green, and blue microlenses in different shapes by changing the thicknesses of resist films for forming the red, green, and blue microlenses as a method of manufacturing a single-chip color CCD.

In the method disclosed in Japanese Patent Laid-Open No. 7-38075, since the red, green, and blue resist films for forming microlenses must have different thicknesses, the exposure process and the developing process must be performed for each color. The number of manufacturing processes increases, and alignment errors may occur between the microlenses of different colors. In addition, since the resist film forming process, the exposure process, and the developing process must be performed a plurality of number of times. The shape of the microlens formed previously changes through the processes of forming the remaining microlenses.

### SUMMARY OF THE INVENTION

The first aspect of the present invention is to provide a technique advantageous in simplifying the manufacturing processes of a microlens array and/or preventing alignment errors between the microlenses.

According to the first aspect of the present invention, there is provided a method of manufacturing a microlens array, the method comprising forming a resist film on a structure including a plurality of light-receiving portions, exposing the resist film using a photomask in which a plurality of lens patterns for forming a plurality of microlenses are arranged, forming a resist pattern by developing the exposed resist film, and forming the plurality of microlens by annealing the resist pattern, wherein the plurality of lens patterns include lens patterns having exposure light transmittance distributions different from each other.

The second aspect of the present invention is to provide a technique advantageous in simplifying the manufacturing processes of a solid-state image sensor and/or preventing alignment errors between microlenses.

According to the second aspect of the present invention, there is provided a method of manufacturing a solid-state image sensor, the method comprising forming a structure including a plurality of light-receiving portions, forming a resist film on the structure, exposing the resist film using a photomask in which a plurality of lens patterns for forming a plurality of microlenses are arranged, forming a resist pattern by developing the exposed resist film, and forming the plurality of microlenses by annealing the resist pattern, wherein the plurality of lens patterns include lens patterns having exposure light transmittance distributions different from each other.

The third aspect of the present invention is to provide a solid-state image sensor having a novel structure.

According to the third aspect of the present invention, there is provided a solid-state image sensor including a first pixel having a focus detecting function and a second pixel having no focus detecting function to obtain an image signal, the first pixel including a first light-receiving portion, a first microlens, and a light-shielding film having an opening arranged between the first light-receiving portion and the first microlens, and the second pixel including a second light-receiving portion and a second microlens, wherein the first microlens and the second microlens have focal distances different from each other, and the first microlens has a focal point in the opening in an in-focus state.

Further features of the present invention will become apparent from the following description of exemplary embodiments with reference to the attached drawings.

### BRIEF DESCRIPTION OF THE DRAWINGS

FIGS. 1A to 1D are views exemplifying a photomask used in the first embodiment;

FIG. 2A shows a solid-state image sensor of the first embodiment and its manufacturing method;

FIG. 2B is a view illustrating the structure of the solid-state image sensor according to the first embodiment;

FIGS. 3A to 3C are views for explaining the second embodiment;

FIG. 4 is a view for explaining the third embodiment;

FIGS. 5A to 5C are views for explaining the third embodiment;

FIG. 6 is a view exemplifying an alignment error between microlenses;

FIG. 7 is a graph exemplifying the sensitivity curve of a positive photosensitive resist material;

FIGS. 8A to 8D are views for explaining the fourth embodiment;

FIGS. 9A to 9C are graphs for explaining the fourth embodiment;

FIGS. 10A to 10C are graphs for explaining the fifth embodiment;

FIG. 11 is a view for explaining the fifth embodiment;

FIGS. 12A to 12C are views for explaining the sixth embodiment;

FIGS. 13A and 13B are graphs for explaining the sixth embodiment; and

FIGS. 14A and 14B are graphs for explaining the seventh embodiment.

### DESCRIPTION OF THE EMBODIMENTS

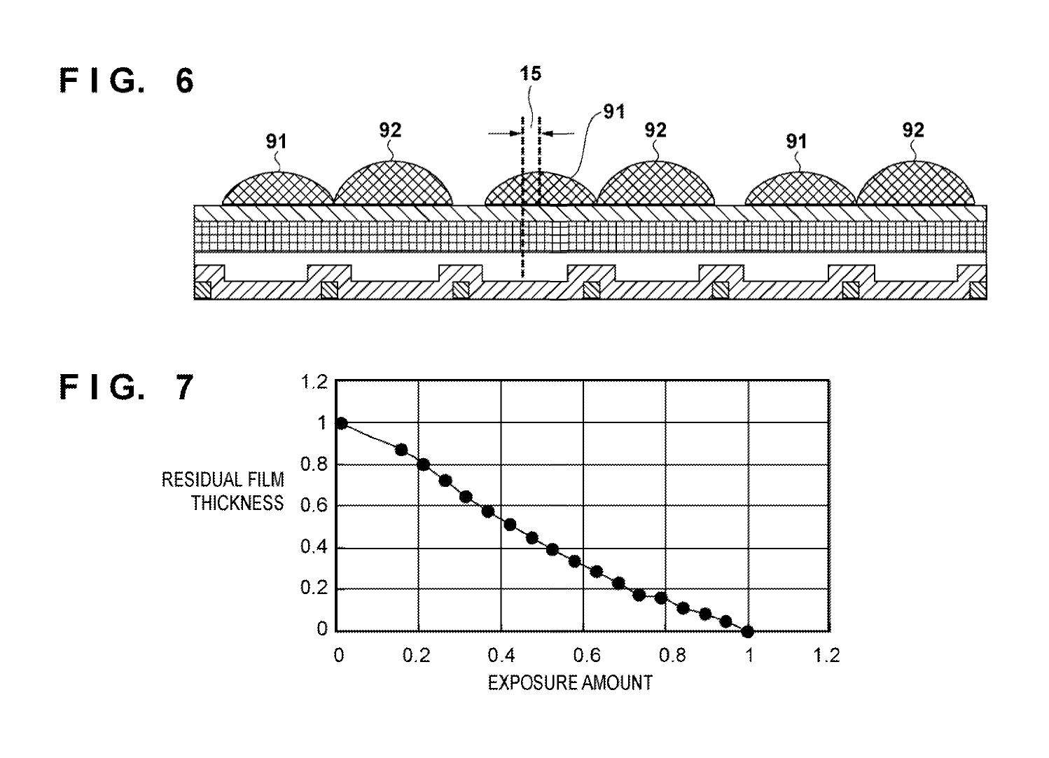

An alignment error between different types of microlenses when they are formed by a plurality of photolithography processes will be described with reference to FIG. 6. In the solid-state image sensor exemplified in FIG. 6, an offset 15 caused by an alignment error is present in a microlens 91 of two types of microlenses 91 and 92. The presence of the offset 15 deviates the focal position (a position in a direction along the image-sensing surface) of the microlens 91 from the design position accordingly. For this reason, a pixel having the microlens 91 has a sensitivity difference from that of a pixel having the microlens 92.

In the first embodiment of the present invention, a latent pattern for forming red, green, and blue microlenses in one exposure process by using a photomask in which lens patterns for forming the red, green, and blue microlenses are arranged is formed. The latent pattern is developed to form a resist pattern. The resist pattern is then annealed to smoothen its surface, thereby forming the curved surface of the microlens.

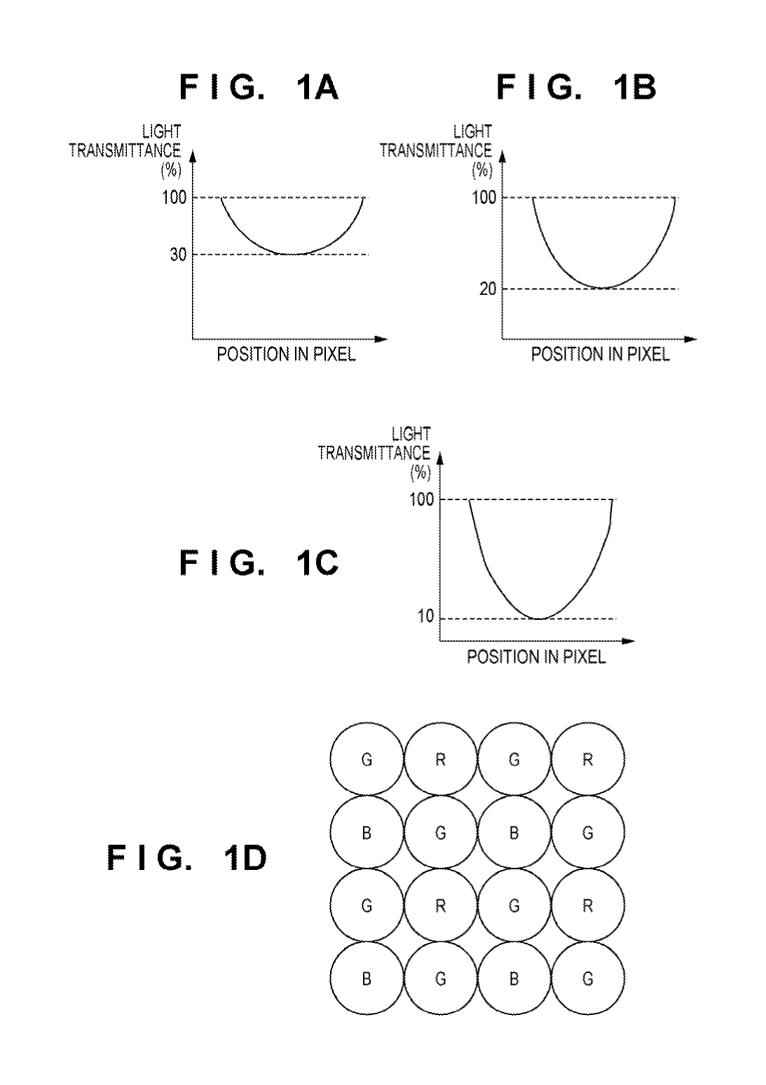

FIG. 1D is a plan view illustrating part of a photomask PM used in the first embodiment of the present invention. Reference symbols B, G, and R denote lens patterns for forming the blue, green, and red pixel microlenses, respectively. FIGS. 1A, 1B and 1C exemplify the exposure light transmittances of the lens patterns for forming the blue, green, and red pixel microlenses. The exposure light transmittance distribution can be given by the area intensity method. The area intensity method is a method of determining intensities in accordance with dot pattern densities. The dot pattern layouts are not given by a circle shown in FIG. 1D, but can be arbitrary layouts which obtain the transmittances shown in FIGS. 1A, 1B, and 1C. In the example shown in FIGS. 1A, 1B, and 1C, the transmittances of the lens patterns for forming the blue, green, and red pixel microlenses at the central positions are 30%, 20%, and 10%, respectively. The light transmittance distribution is determined in consideration of the shape of a microlens to be formed, the sensitivity curve of a resist material, the photomask illumination condition in the exposure apparatus, and the like.

The exposure apparatus uses the photomask PM to form, in the resist film, the latent pattern exposed using the exposure amount distribution corresponding to the transmittances of FIGS. 1A, 1B, and 1C. As a resist material, a material capable of controlling the film thickness (residual film thickness) of the resist left after the developing process in accordance with the exposure amount is used as exemplified in FIG. 7 (sensitivity curve). This makes it possible to form a resist pattern having a film thickness distribution corresponding to the exposure amount distribution. Annealing (baking process) after the developing process allows to obtain blue, green, and red pixel microlenses having different shapes.

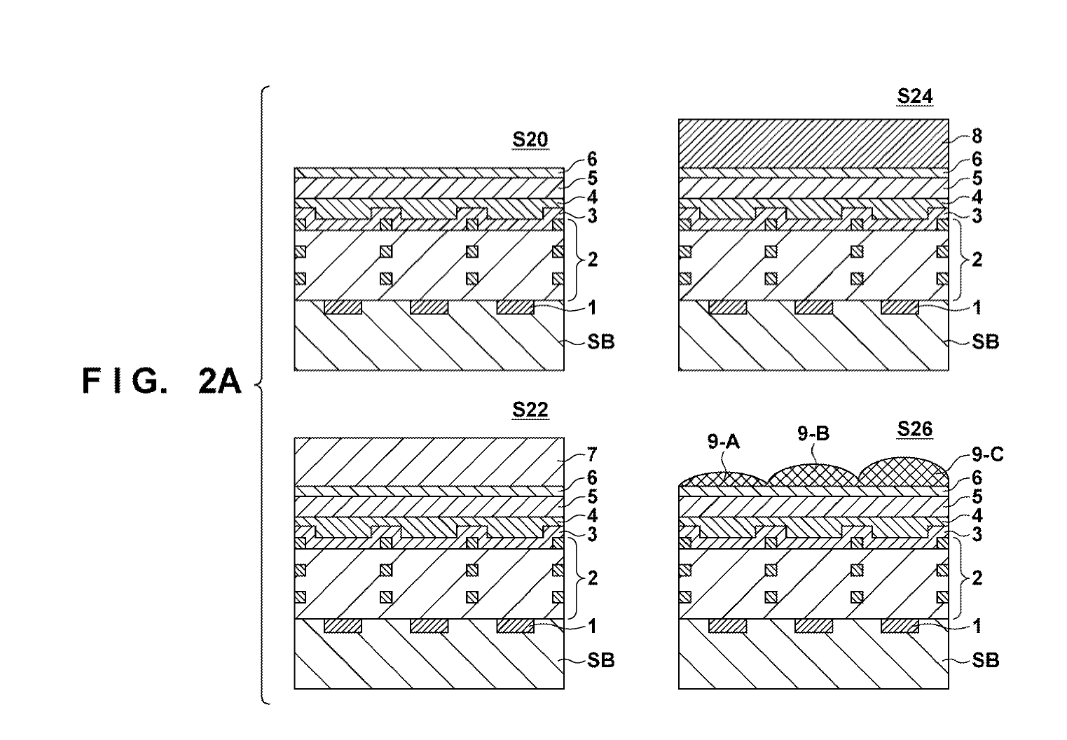

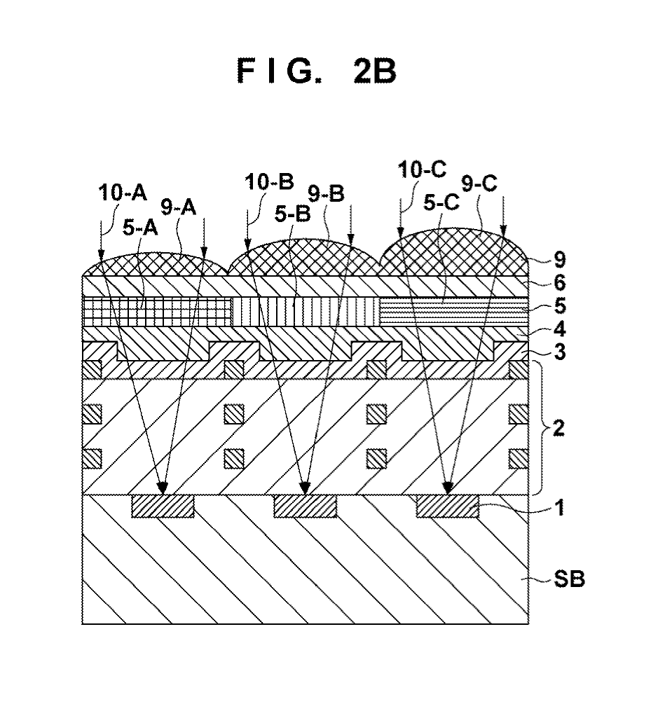

The solid-state image sensor of the first embodiment and its manufacturing method will be described with reference to FIG. 2A. This embodiment will exemplify a CMOS solid-state image sensor. In step S20, a multilayer wiring structure 2 is formed on a semiconductor substrate SB in which a plurality of light-receiving portions (photoelectric transducers) 1 are formed. An insulating film 3 is formed to cover the multilayer wiring structure 2. In step S20, a first planarizing layer 4 is formed on the insulating film 3. A color filter layer 5 is formed on the planarizing layer 4. A second planarizing layer 6 is formed on the color filter layer 5. Note that the multilayer wiring structure 2 can include, for example, a first wiring layer, first interlayer dielectric layer, second wiring layer, second interlayer dielectric layer, and third wiring layer. In FIG. 2A, the color filter layer 5 comprises a single layer for illustrative convenience. However, the color filter layer 5 can include a plurality of color filters corresponding to the blue, green, and red pixels and have an arrangement such as a Bayer arrangement. This makes it possible to form a structure including the plurality of light-receiving portions 1.

Next, in step S22, a resist material capable of controlling the film thickness (residual film thickness) of the resist left after the developing process in accordance with the exposure amount as shown in FIG. 7 is applied to the second planarizing layer 6 of the structure prepared in step S20. The resist material is baked to form a resist film 7. In step S24, the resist film 7 is exposed using the photomask PM described with reference to FIG. 1, thereby forming a latent pattern 8 in the resist film 7. In step S26, the latent pattern 8 is developed and annealed to form a microlens array including microlenses 9-A, 9-B and 9-C. In this case, the microlenses 9-A, 9-B, and 9-C exemplify the blue, green, and red pixel microlenses, respectively. Note that, as shown in FIG. 2A, although the blue, green, and red pixel microlenses are aligned in a line for illustrative convenience, but can be arranged in practice in accordance with the Bayer arrangement or the like.

FIG. 2B is a sectional view illustrating the structure of the solid-state image sensor prepared by the manufacturing method shown in FIG. 2A. The microlenses 9-A, 9-B, and 9-C are arranged for the pixels having a blue pixel color filter 5-A, green pixel color filter 5-B, and red pixel color filter 5-C, respectively. Reference numerals 10-A, 10-B, and 10-C denote blue, green, and red light rays, respectively. Referring to FIG. 2B, light is focused on the surface (light-receiving surface) of the light-receiving portion 1. However, the microlenses may be configured to focus light at a position different from the light-receiving surface, as needed.

As described above, according to the first embodiment, the blue, green, and red pixel microlenses can be formed by one exposure process. This can contribute to simplification of the process and reduction of alignment errors between the microlenses. In addition, according to the first embodiment, the shape of the microlenses formed previously in the repeated formation process of the microlenses will not be changed by the formation process of remaining microlenses.

In the first embodiment, the shapes of all the microlenses for the same color are not limited to one. The shapes of the microlenses for the same color can be different from each other by adjusting the light transmittance distributions of the respective lens patterns of the photomask PM.

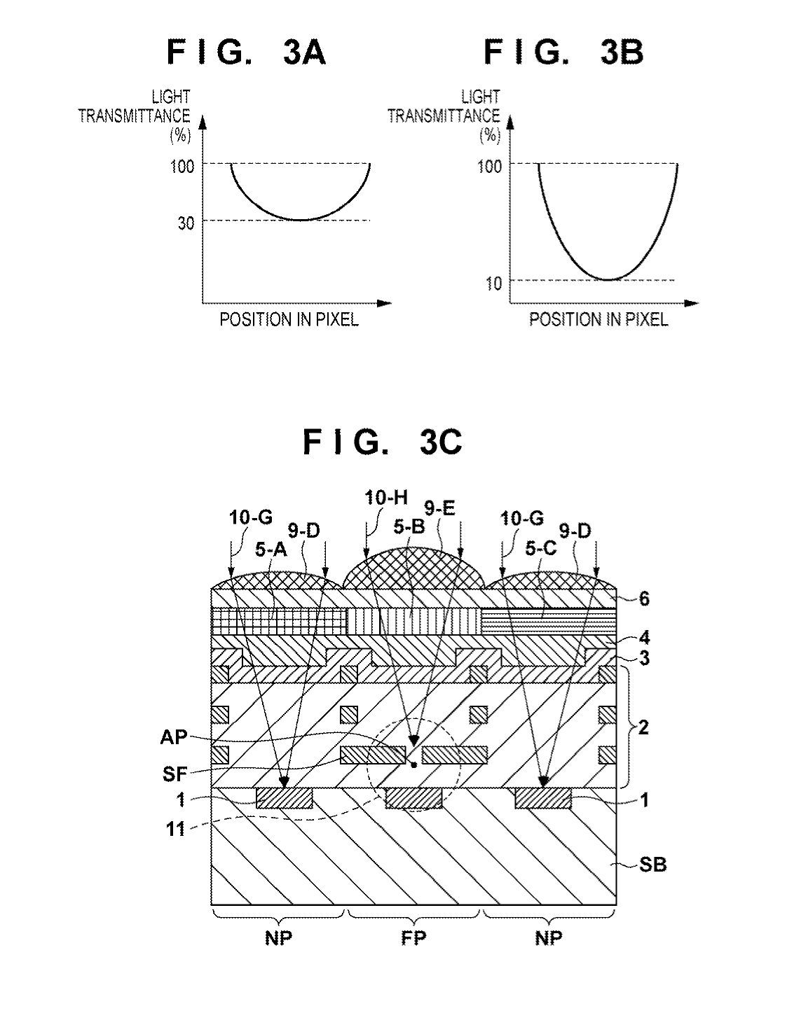

The second embodiment of the present invention will be described with reference to FIGS. 3A to 3C. The method of manufacturing a solid-state image sensor of the second embodiment is the same as that of the first embodiment except a photomask for forming microlenses. FIG. 3C is a sectional view illustrating the structure of the solid-state image sensor according to the second embodiment. The solid-state image sensor according to the second embodiment includes a pixel FP (first pixel) having a focus detecting function (to be referred to as an AF pixel hereinafter) in addition to a normal pixel NP (second pixel) for obtaining an image signal. The AF pixel FP includes a light-receiving portion (first light-receiving portion) 11 having the same shape as or shape different from that of the light-receiving portion (second light-receiving portion) 1 of the normal pixel NP, a microlens (first microlens) 9-E, and a light-shielding film SF arranged between the light-receiving portion 11 and the microlens 9-E. Using the paired signals of the plurality of AF pixels FP allows to detect the phase differences.

The AF pixel FP includes the light-shielding film SF on the light-receiving portion 11. The light-shielding film SF has an opening AP. The center of the opening AP is shifted from the center of the light-receiving portion 11. Since an output value from the AF pixel FP changes depending on the focus state (defocus amount), the focus state can be detected based on the output value. The focal length of the microlens 9-E of the AF pixel FP is different from that of the microlens (second microlens) 9-D of the normal pixel NP. In the in-focus state, the microlens 9-E of the AF pixel FP has a focal point in the opening AP of the light-shielding film SF. In the in-focus state, the microlens 9-D of the normal pixel NP can have a focal point on, for example, the surface of the light-receiving portion 1, but may be a focal point shifted from the light-receiving surface. Note that the in-focus state indicates a state in which the photographing lens of a camera focuses an object image on the image-sensing surface of the solid-state image sensor.

In the second embodiment, the exposure process uses a photomask having different exposure light transmittance distributions between the lens pattern for forming the microlens 9-E of the AF pixel FP and the lens pattern for forming the microlens 9-D of the normal pixel NP. This makes it possible to make the focal length of the microlens 9-E of the AF pixel FP different from that of the microlens 9-D of the normal pixel NP. For example, the microlens 9-E of the AF pixel FP and the microlens 9-D of the normal pixel NP can have different heights and different curvatures. Referring to FIG. 3C, reference numerals 10-G and 10-H denote the incident light loci and focal points. FIGS. 3A and 3B exemplify the exposure light transmittances of the lens patterns for forming the microlenses of the normal pixel NP and the AF pixel FP. In the examples of FIGS. 3A and 3B, the exposure light transmittances of the lens patterns for forming the microlenses of the normal pixel NP and the AF pixel FP at the central positions are 30% and 10%, respectively. In the second embodiment, the focal positions of the blue, green, and red pixels of the normal pixels NP may be made different from each other as in the first embodiment.

The second embodiment can form microlenses of the normal and AF pixels having different focal positions by one exposure process. This can contribute to simplification of the process and reduction of alignment errors between the microlenses. In addition, according to the second embodiment, the shape of the microlenses formed previously in the repeated formation process of the microlenses will not be changed by the formation process of remaining microlenses.

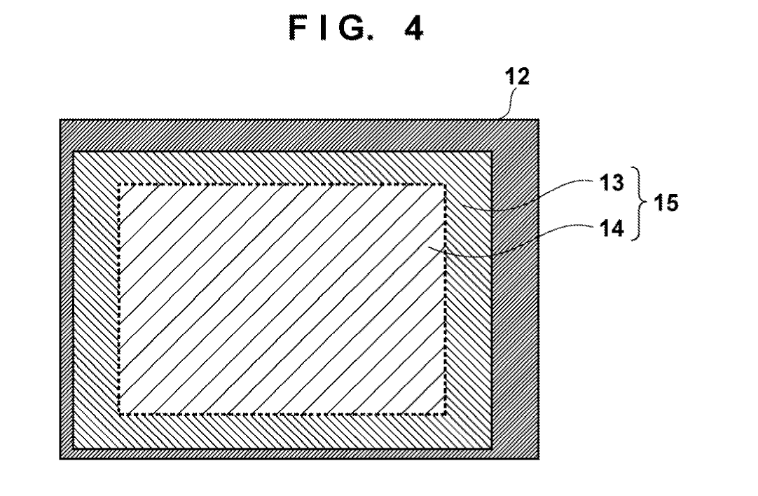

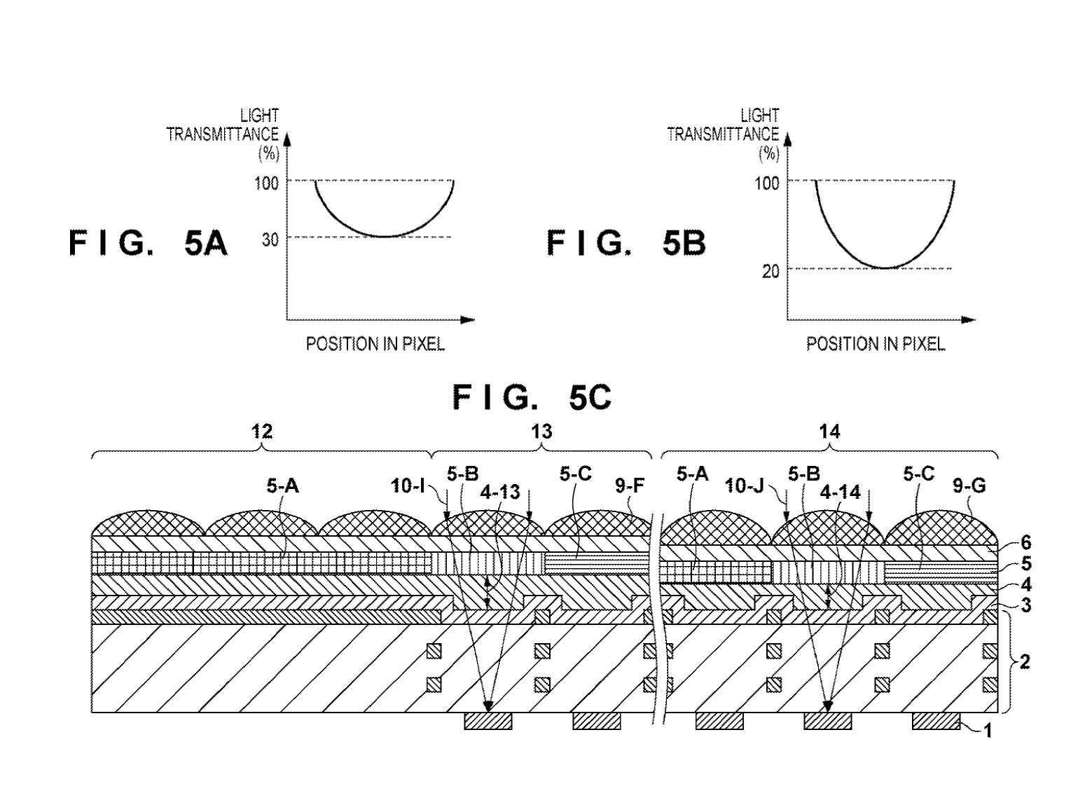

The third embodiment of the present invention will be described with references to FIGS. 4 and 5A to 5C. A solid-state image sensor of the third embodiment has an effective pixel region 15 and an ineffective pixel region 12, as shown in FIG. 4. An OB region (optical black region) 12 is a region in which the wiring layer pattern of the uppermost layer of a multilayer wiring structure 2 extends. The OB region 12 includes an OB region (optical black region) having a light-receiving portion 1 as in at least the effective pixel region 15 or includes a circuit region in which a driving circuit is arranged. The effective pixel region 15 can includes, for example, a central region 14 and an outer region 13 arranged around it. FIG. 5C is a sectional view illustrating the structure of the central region 14, the outer region 13, and the ineffective pixel region 12 of the solid-state image sensor of the third embodiment. When the central region 14, outer region 13, and ineffective pixel region 12 in FIG. 5C are compared with each other, the thickness of a first planarizing layer 4 in the central region 14 is different from that in the outer region 13. Letting 4-14 and 4-13 be the thicknesses of the first planarizing layer 4 in the central region 14 and the first planarizing layer 4 in the outer region 13, respectively, relation (4-14)<(4-13) is established. This is because the pattern density of the wiring layer of the uppermost layer in the multilayer wiring structure 2 in the ineffective pixel region 12 is higher than that in the central region 14.

When identical microlenses are formed in the effective pixel region 15 including the central region 14 and the outer region 13 in this state, the positional relationship in the focal position and light-receiving surface of the microlens in the central region 14 becomes different from that in the outer region 13. For this reason, the shapes (for example, heights and curvatures) of a microlens 9-G of the pixel of the central region 14 and a microlens 9-F of the outer region 13 are adjusted so as to make the positional relationship in the focal position and light-receiving surface of the microlens in the central region 14 match that in the outer region 13. Reference numerals 10-I and 10-J denote light rays entering the microlenses 9-F and 9-G, respectively. Even if the thickness of the first planarizing layer 4 in the central region 14 is different from that in the outer region 13, the relationships in the focal position and light-receiving surface of the incident light obviously match each other.

The thickness of the first planarizing layer 4 in the outer region 13 increases at a position closer to the ineffective pixel region 12 and decreases at a position far away from the ineffective pixel region 12 and becomes gradually closer to the thickness of the central region 14. A region in which the thickness of the first planarizing layer 4 changes falls within the range of several ten to several hundred μm from the boundary from the ineffective pixel region 12. This range depends on the planarizing layer used and the pattern density of the wiring layer of the uppermost layer. The shape of the microlens 9-F of the pixel of the outer region 13 may be changed depending on this change. FIGS. 5A and 5B exemplify the exposure light transmittances of the patterns by which the microlenses of the pixels arranged in the outer region 13 and the central region 14 are formed. In the examples shown in FIGS. 5A and 5B, the exposure light transmittances at the central positions of the patterns for forming the microlenses of the pixels of the outer region 13 and the central region 14 are 30% and 20%, respectively.

In the third embodiment, the focal positions of the blue, green, and red pixel microlenses may be made different from each other as in the first embodiment, or an AF pixel may be included as in the second embodiment.

In the third embodiment, a plurality of microlenses having different shapes can be formed by one exposure process depending on the pixel position (for example, the position in the outer region 13 or central region 14). This can contribute to simplification of the process and reduction of alignment errors between the microlenses. In addition, according to the third embodiment, the shape of the microlenses formed previously in the repeated formation process of the microlenses will not be changed by the formation process of remaining microlenses.

The first to third embodiments are practical examples each for a solid-state image sensor manufacturing method including a process for exposing a resist film using a photomask in which a plurality of lens patterns for forming a plurality of microlenses are arranged. The plurality of lens patterns include at least two lens patterns having different exposure light transmittance distributions. These two lens patterns can have light transmittance distributions depending on the color of the pixel, and/or the function of the pixel (normal pixel or AF pixel), and/or the position (or belonging region).

The microlenses obtained in each of the first to third embodiments can be further used as a microlens formation mask. In this case, a microlens material must be arranged below the microlens formation mask obtained in each of the first to third embodiments, and the microlens material is etched including the microlens formation mask, thereby forming microlenses.

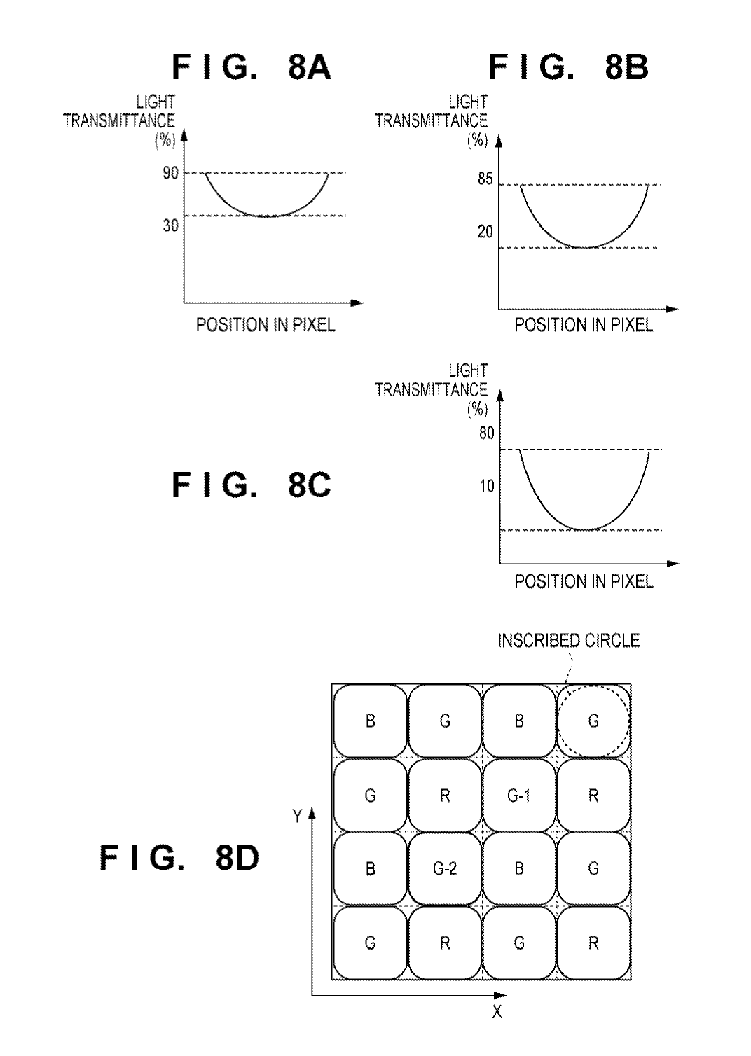

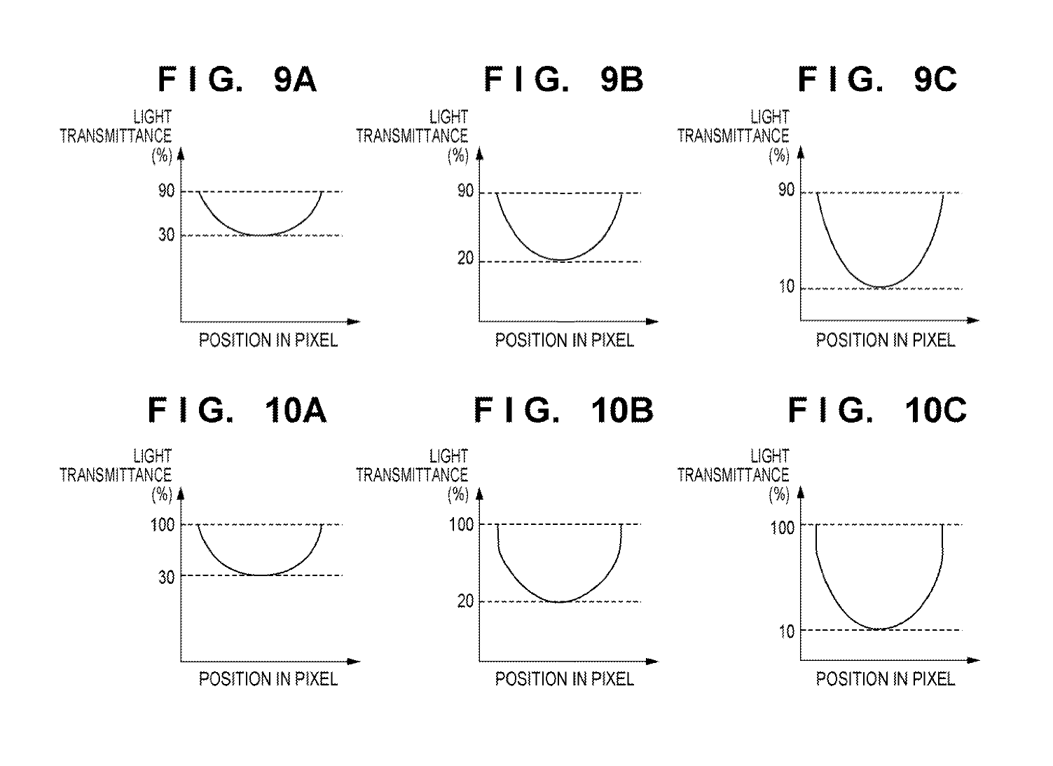

The fourth embodiment of the present invention will be described with reference to FIGS. 8A to 8D and 9A to 9C. FIG. 8D is a plan view illustrating part of a photomask used in the fourth embodiment of the present invention. Reference symbols B, G, and R denote lens patterns for forming blue, green, and red pixel microlenses, respectively. FIGS. 8A, 8B, and 8C exemplify the exposure light transmittances of the lens patterns for forming the blue, green, and red pixel microlenses, respectively.

In the first embodiment, when a microlens is larger than a circle inscribed in a pixel region indicated by a dotted line, as shown in FIG. 8D, continuity of the photomask transmittance is lost at a boundary where the microlenses are adjacent to each other, as shown in FIG. 8A, 8B, or 8C. In particular, since the shapes of the blue and red pixel microlenses adjacent to the green pixel microlens are different from each other, the shape of the green pixel microlens at a section along the X direction is different from that along the Y direction. In addition, since green pixel microlenses G-1 and G-2 shown in FIG. 8D have different colors of color filters adjacent in the X and Y directions, these microlenses may have different shapes.

The fourth embodiment of the present invention is useful to solve the above problem. FIGS. 9A, 9B, and 9C exemplify the exposure light transmittances of the lens patterns for forming blue, green, and red pixel microlenses, respectively. In the fourth embodiments, the boundaries where microlenses are adjacent to each other have the same transmittance. The continuity of the photomask transmittance is kept at the boundary where the microlenses arranged on color filters having different colors are adjacent to each other. When microlenses are formed using this photomask as in the first embodiment, the shape of the green pixel microlens at a section along the X direction is the same as that along the Y direction. In addition, the green pixel microlenses G-1 and G-2 shown in FIG. 8D have the same shape. Even in the fourth embodiment, blue, green, and red microlenses having different shapes can be obtained.

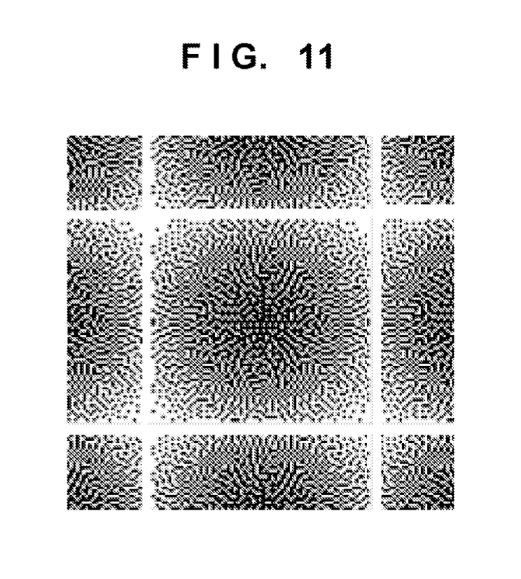

The fifth embodiment of the present invention will be described with reference to FIGS. 10A to 10C and 11. The fifth embodiment is also useful to solve the problem of the first embodiment. FIGS. 10A, 10B, and 10C exemplify the exposure light transmittances of lens patterns for forming blue, green, and red pixel microlenses, respectively. The lens patterns for forming the blue, green, and red pixel microlenses are identical to those in the fourth embodiment, as shown in FIG. 8D. FIG. 11 shows a photomask pattern having slits at positions corresponding to the boundaries of the adjacent pixels (that is, boundary positions between the lens patterns).

By forming the above slits, the transmittance at the boundary of the adjacent pixels becomes 100%. In this case, the width of each slit is desirably an exposure wavelength or less, and for example, can be set to 0.06 μm.

As described above, since the photomask transmittance becomes uniform across the boundaries of the adjacent microlenses arranged on the color filters having different colors, the continuity of the transmittance is maintained. When microlenses are formed using this photomask as in the first embodiment, the shape of the green pixel microlens at a section along the X direction is the same as that in the Y direction. The green pixel microlenses G-1 and G-2 shown in FIG. 8D have the same shape. Even in the fifth embodiment, blue, green, and red pixel microlenses having different shapes can be obtained.

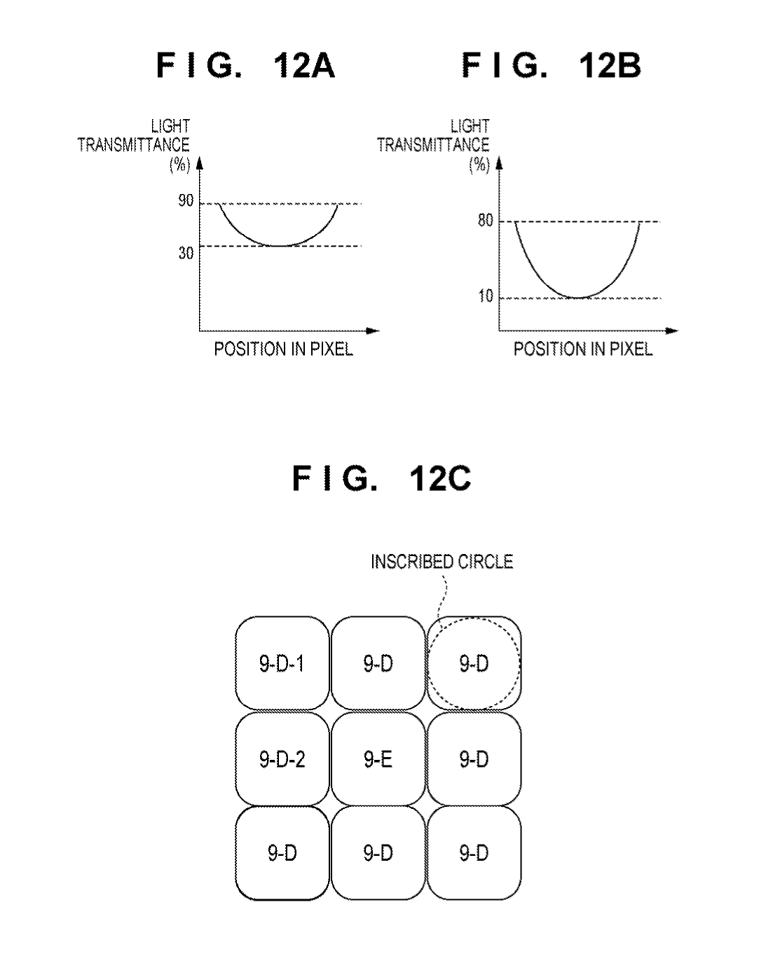

The sixth embodiment of the present invention will be described with reference to FIGS. 12A to 12C and 13A and 13B. FIG. 12C is a plan view illustrating part of a photomask used in the sixth embodiment of the present invention. Reference numerals 9-D and 9-E denote lens patterns for forming microlenses for a normal pixel NP and an AF pixel FP, respectively. FIGS. 12A and 12B exemplify exposure light transmittances of the lens patterns for forming the microlenses for the normal pixel NP and the AF pixel FP.

The sixth embodiment uses the photomask having different exposure light transmittance distributions between the lens pattern for forming the microlens 9-E for the AF pixel FP and the lens pattern for forming the microlens 9-D for the normal pixel NP. Assume that the microlens 9-E for the AF pixel FP and the microlens 9-D for the normal pixel NP have different heights and different curvatures. Assume also that the microlenses 9-E are spaced apart from each other by one or more pixels via the microlenses 9-D. That is, at least one of the microlenses 9-D is arranged between one of the microlenses 9-E and another of the microlenses 9-E.

When a microlens is larger than a circle inscribed in a pixel region indicated by a dotted line, as shown in FIG. 12C, continuity of the photomask transmittance is lost at a boundary where the microlenses are adjacent to each other, as shown in FIG. 12A or 12B. A microlens 9-D-1 for the normal pixel NP adjacent to the microlens 9-E for the AF pixel FP has a shape different from that of 9-D-2 adjacent for the microlens for the normal pixel NP.

The sixth embodiment of the present invention is useful to solve the above problem. FIGS. 13A and 13B exemplify the exposure light transmittances of the lens patterns for forming microlenses for the AF pixel FP and the normal pixel NP, respectively. In the sixth embodiment, the boundaries where microlenses are adjacent to each other have the same transmittance. The continuity of the photomask transmittance is kept at the boundary where the microlenses for the AF pixel FP and the normal pixel NP are adjacent to each other. When microlenses are formed using this photomask as in the second embodiment, the shape of the microlens 9-D-1 for the normal pixel NP adjacent to the microlens 9-E for the AF pixel FP shown in FIG. 12C is the same as that of 9-D-2 adjacent to the microlens for the normal pixel NP. Even in the sixth embodiment, microlenses for the AF pixel FP and the normal pixel NP having different shapes can be obtained.

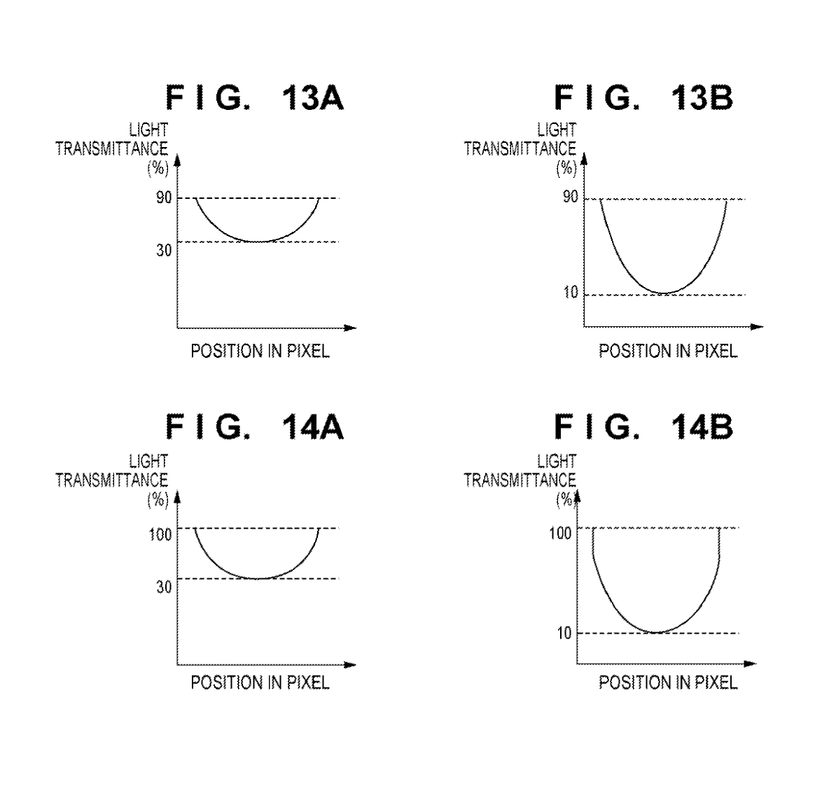

The seventh embodiment of the present invention will be described with reference to FIGS. 14A and 14B. The seventh embodiment is also useful to solve the problem in the second embodiment. FIGS. 14A and 14B exemplify exposure light transmittances of lens patterns for forming microlenses for an AF pixel FP and a normal pixel NP, respectively. The seventh embodiment also includes slits at positions corresponding to the boundaries of the adjacent pixels (that is, boundary positions between the lens patterns). The transmittance at the boundary of the adjacent pixels is set to 100%.

The width of each slit is desirably an exposure wavelength or less, and for example, can be set to 0.06 μm. As described above, since the photomask transmittance becomes uniform across the boundaries of the adjacent microlenses arranged on the color filters having different colors, the continuity of the transmittance is maintained. Microlenses are formed using this photomask as in the second embodiment. A microlens 9-D-1 for the normal pixel NP adjacent to a microlens 9-E for the AF pixel FP shown in FIG. 12C has the same shape as that of 9-D-2 adjacent to the microlens for the normal pixel NP. Even in the seventh embodiment, microlenses for the AF pixel FP and the normal pixel NP having different shapes can be obtained.

The above embodiments can be appropriately combined.

As an application example of a solid-state image sensor according to each of the above embodiments, a camera incorporating the solid-state image sensor will be exemplified. The concept of the camera includes not only devices having a photographic function as the main purpose, but also devices (for example, a personal computer and a portable terminal) having a photographic function as an auxiliary purpose. The camera includes the solid-state image sensor according to the present invention exemplified as each embodiment described above and a processing unit for processing signals output from the solid-state image sensor. The processing unit can include, for example, an A/D converter and a processor for processing digital data output from the A/D converter.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application Nos. 2010-182592, filed Aug. 17, 2010 and 2011-162454, filed Jul. 25, 2011 which are hereby incorporated by reference herein in their entirety.

What is claimed is:

1. A method of manufacturing a microlens array, the method comprising:
forming a resist film on a structure including a plurality of light-receiving portions;
exposing the resist film using a photomask in which a plurality of lens patterns for forming a plurality of microlenses are arranged;
forming a resist pattern by developing the exposed resist film; and
forming the plurality of microlens by annealing the resist pattern,
wherein the plurality of lens patterns include lens patterns having exposure light transmittance distributions different from each other.

2. The method according to claim 1, wherein each of the lens patterns having exposure light transmittance distributions different from each other includes a lens pattern that is determined in accordance with a color of a pixel including the light-receiving portion.

3. The method according to claim 1, wherein the lens patterns having exposure light transmittance distributions different from each other include a lens pattern of a pixel having a focus detecting function and a lens pattern of a normal pixel having no focus detecting function.

4. The method according to claim 1, wherein each of the lens patterns having exposure light transmittance distributions different from each other includes a lens pattern that is determined in accordance with a position of a pixel including light-receiving portions.

5. The method according to claim 1, wherein a light transmittance is continuous at a boundary of adjacent microlenses among the plurality of lens patterns.

6. A method of manufacturing a solid-state image sensor, the method comprising:
forming a structure including a plurality of light-receiving portions;
forming a resist film on the structure;
exposing the resist film using a photomask in which a plurality of lens patterns for forming a plurality of microlenses are arranged;
forming a resist pattern by developing the exposed resist film; and
forming the plurality of microlenses by annealing the resist pattern,
wherein the plurality of lens patterns include lens patterns having exposure light transmittance distributions different from each other.

7. The method according to claim 6, wherein a light transmittance is continuous at a boundary of adjacent microlenses among the plurality of lens patterns.

8. A solid-state image sensor including a first pixel having a focus detecting function and a second pixel having no focus detecting function to obtain an image signal,
the first pixel including a first light-receiving portion, a first microlens, and a light-shielding film having an opening arranged between the first light-receiving portion and the first microlens, and
the second pixel including a second light-receiving portion and a second microlens,
wherein the first microlens and the second microlens have focal distances different from each other, and the first microlens has a focal point in the opening in an in-focus state.
